(19) United States
(12) Patent Application Publication
(10) Pub. No.: US 2016/0365474 A1
(43) Pub. Date: Dec. 15, 2016

(54) GROUP III NITRIDE SEMICONDUCTOR LIGHT-EMITTING DEVICE AND PRODUCTION METHOD THEREFOR

(71) Applicant: TOYODA GOSEI CO., LTD., Kiyosu-shi (JP)

(72) Inventor: Naoyuki NAKADA, Kiyosu-shi (JP)

(21) Appl. No.: 15/179,757

(22) Filed: Jun. 10, 2016

(30) Foreign Application Priority Data
Jun. 15, 2015 (JP) 2015-120683

(51) Int. Cl. H01L 33/00; H01L 33/24; H01L 33/06; H01L 33/32

(52) U.S. Cl. CPC H01L 33/0025; H01L 33/32; H01L 33/24; H01L 33/06; H01L 33/0075

(57) ABSTRACT

There is provided a Group III nitride semiconductor light-emitting device in which reduction in the light emission amount in an operation at a high temperature is suppressed. The light-emitting device has an n-side superlattice layer, a light-emitting layer, and a p-type cladding layer. The light-emitting device has a plurality of pits extending from the n-type semiconductor layer to the p-type semiconductor layer. A pit diameter D1 of a first pit at an interface between the light-emitting layer and the n-side superlattice layer is larger than a pit diameter D2 of the first pit at an interface between the light-emitting layer and the p-type cladding layer. The pit diameter D1 and the pit diameter D2 satisfy the following condition: 0.15≦(D1−D2)/T≦1.0. Here, the thickness T is the thickness of the light-emitting layer.

### BACKGROUND OF THE INVENTION

### Field of the Invention

The present invention relates to a Group III nitride semiconductor light-emitting device and a production method therefor, particularly to a method for producing a Group III nitride semiconductor light-emitting device having pits.

### Background Art

The Group III nitride semiconductor light-emitting device has a light-emitting layer which emits light through recombination of electrons and holes, an n-type semiconductor layer, and a p-type semiconductor layer. When producing the Group III nitride semiconductor light-emitting device, semiconductor layers are epitaxially grown on a substrate. In this case, threading dislocation occurs in the semiconductor layer due to lattice mismatch between the substrate and the semiconductor layer. Pits are formed in the threading dislocation during the growth.

Such pits have the effect of reducing the drive voltage. For example, Japanese Patent Application Laid-Open (kokai) No. 2008-218746 discloses that the drive voltage is reduced using facet planes of pits (refer to paragraphs [0020]-[0021] of Japanese Patent Application Laid-Open (kokai) No. 2008-218746).

The light-emitting device for illumination is often placed in a relatively high temperature environment. However, in such a high temperature environment, the emission efficiency of the light-emitting device may be reduced because carrier leakage occurs around the pits. Therefore, a technique to fill the pits with i-GaN is also devised. In this case, a distance between the n-type semiconductor layer and the p-type semiconductor layer is larger than that when the pits are filled with the p-type semiconductor layer. Thereby, carrier leakage can be suppressed, but the drive voltage is increased.

### SUMMARY OF THE INVENTION

The present inventions have been accomplished for solving the aforementioned problems involved in conventional techniques. Accordingly, an object of the present inventions is to provide a Group III nitride semiconductor light-emitting device in which reduction in the light emission amount in an operation at a high temperature is suppressed, and a production method therefor.

Accordingly, in a first aspect of the embodiment related with the present inventions, there is provided a Group III nitride semiconductor light-emitting device comprising an n-type semiconductor layer, a light-emitting layer on the n-type semiconductor layer, and a p-type semiconductor layer on the light-emitting layer. The Group III nitride semiconductor light-emitting device has a plurality of pits extending from the n-type semiconductor layer to the p-type semiconductor layer. The pit diameter D1 of the first pit at an interface between the light-emitting layer and the n-type semiconductor layer, is larger than the pit diameter D2 of the first pit at an interface between the light-emitting layer and the p-type semiconductor layer. The pit diameter D1 and the pit diameter D2 satisfy the following condition:

0.15≦(D1−D2)/T≦1.0

T: Thickness of the light-emitting layer

The Group III nitride semiconductor light-emitting device emits a sufficient amount of light even in an operation at a high temperature. In other words, there is little difference between the light emission amount at a room temperature and the light emission amount at a high temperature. In the light-emitting device, each light-emitting layer inside each pit has a sufficient thickness. Therefore, carrier leakage hardly occurs around the pits in an operation at a high temperature.

A second aspect of the embodiment related with the present inventions is drawn to a specific embodiment of the Group III nitride semiconductor light-emitting device, wherein the light-emitting layer has a flat portion disposed outside the first pit and an inclined portion disposed inside the first pit and connected from the flat portion. The thickness of the flat portion and the thickness of the inclined portion satisfy the following condition:

0.56≦B/A≦0.9

A: Thickness of the flat portion of the light-emitting layer

B: Thickness of the inclined portion of the light-emitting layer

In a third aspect of the embodiment related with the present inventions, there is provided a method for producing a Group III nitride semiconductor light-emitting device comprising an n-type semiconductor layer, a light-emitting layer on the n-type semiconductor layer, and a p-type semiconductor layer on the light-emitting layer. Through employment of the method, a plurality of pits is formed so as to extend from the n-type semiconductor layer to the p-type semiconductor layer. A plurality of pits are formed so that the pit diameter D1 of the first pit at the interface between the light-emitting layer and the n-type semiconductor layer is larger than the pit diameter D2 of the first pit at the interface between the light-emitting layer and the p-type semiconductor layer. The pit diameter D1 and the pit diameter D2 satisfy the following condition:

0.15≦(D1−D2)/T≦1.0

T: Thickness of the light-emitting layer

A fourth aspect of the embodiment related with the present inventions is drawn to a specific embodiment of the method for producing a Group III nitride semiconductor light-emitting device, wherein the light-emitting layer has a flat portion disposed outside the first pit, and an inclined portion disposed inside the first pit and connected from the flat portion. The thickness of the flat portion and the thickness of the inclined portion satisfy the following condition:

0.56≦B/A≦0.9

A: Thickness of the flat portion of the light-emitting layer

B: Thickness of the inclined portion of the light-emitting layer

A fifth aspect of the embodiment related with the present inventions is drawn to a specific embodiment of the method for producing a Group III nitride semiconductor light-emitting device, wherein as a light-emitting layer, an InGaN well layer, a capping layer on the well layer, and a barrier layer containing In on the capping layer, are formed. The temperature is gradually increased when forming the capping layer.

The present inventions, disclosed in the specification, provide a Group III nitride semiconductor light-emitting device in which reduction in the light emission amount in an operation at a high temperature is suppressed and a production method therefor.

### BRIEF DESCRIPTION OF THE DRAWINGS

Various other objects, features, and many of the attendant advantages of the present techniques will be readily appreciated as the same becomes better understood with reference to the following detailed description of the preferred embodiments when considered in connection with the accompanying drawings, in which:

FIG. 1 is a schematic view of the structure of a Group III nitride semiconductor light-emitting device according to an embodiment;

FIG. 2 is a schematic view of the layer structure of the semiconductor layers forming the Group III nitride semiconductor light-emitting device according to the embodiment;

FIG. 3 is a schematic view of a pit provided in the light-emitting device according to an embodiment (part 1);

FIG. 4 is a schematic view of a pit provided in the light-emitting device according to an embodiment (part 2);

FIG. 5 is a schematic view illustrating the method for producing a light-emitting device according to an embodiment (part 1);

FIG. 6 is a schematic view illustrating the method for producing the light-emitting device according to an embodiment (part 2);

FIG. 7 is a graph showing the relationship between the In doping amount to the barrier layer and the pit diameter;

FIG. 8 is a graph showing the relationship between the In doping amount to the barrier layer and the one-period thickness of the light-emitting layer;

FIG. 9 is a graph showing the total radiant flux of the light-emitting device at a room temperature;

FIG. 10 is a graph showing the drive voltage of the light-emitting device at a room temperature; and

FIG. 11 is a graph showing the relationship between the pit diameter change rate and the luminous intensity maintenance rate.

### DETAILED DESCRIPTION OF PREFERRED EMBODIMENT

A specific embodiment of the semiconductor light-emitting device and the production method therefor will next be described with reference to the drawings. However, the embodiment should not be construed as limiting the techniques thereto. Needless to say, the structures of the layers and electrodes forming the below-mentioned light-emitting device are merely examples, and may differ from those exemplified in the below-described embodiment. The thickness of each layer, which is schematically shown in the drawings, does not correspond to its actual value. Also, the dimensions of the pits shown in the drawings are larger than the actual values.

### 1. Semiconductor Light-Emitting Device

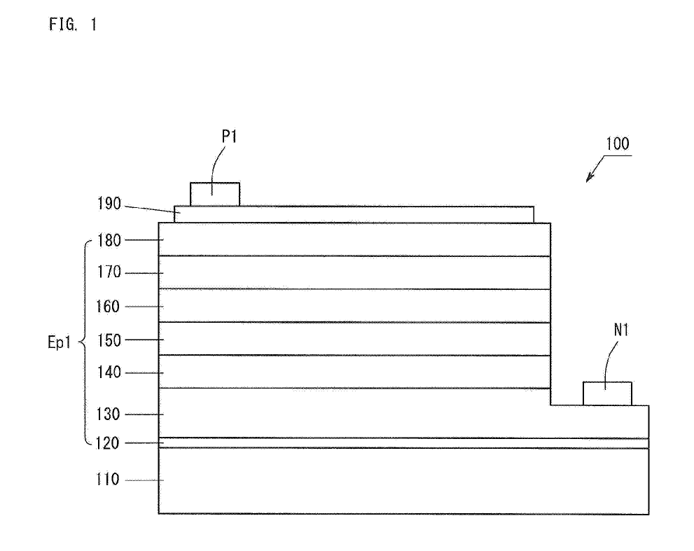

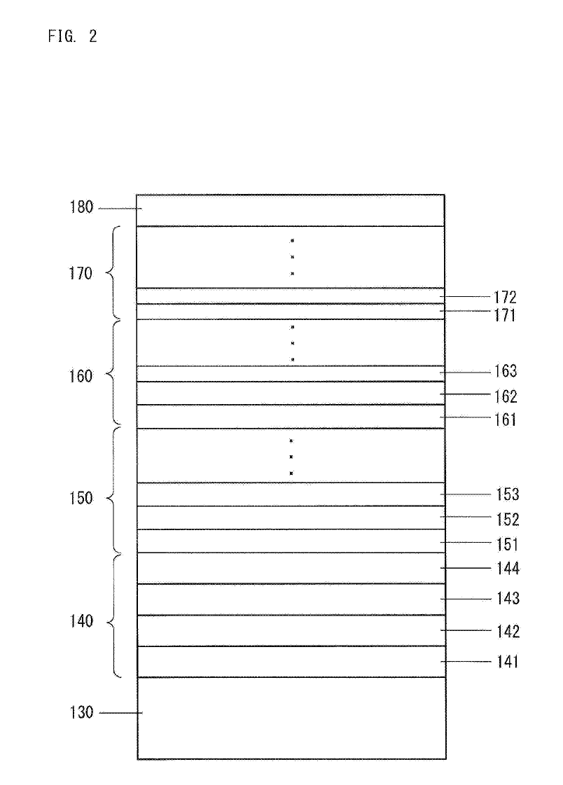

FIG. 1 is a schematic view of the structure of a Group III nitride semiconductor light-emitting device 100 according to the embodiment. FIG. 2 is a schematic view of the layer structure of the semiconductor layers in the light-emitting device 100. The light-emitting device 100 is a face-up-type semiconductor light-emitting device. The light-emitting device 100 has a plurality of semiconductor layers formed of a Group III nitride semiconductor.

As shown in FIG. 1, the light-emitting device 100 has a substrate 110, a low-temperature buffer layer 120, an n-type contact layer 130, an n-side electrostatic breakdown preventing layer 140, an n-side superlattice layer 150, a light-emitting layer 160, a p-type cladding layer 170, a p-type contact layer 180, a transparent electrode 190, an n-electrode N1, and a p-electrode P1. A semiconductor layer Ep1 comprises the low-temperature buffer layer 120, the n-type contact layer 130, the n-side electrostatic breakdown preventing layer 140, the n-side superlattice layer 150, the light-emitting layer 160, the p-type cladding layer 170, and the p-type contact layer 180. The n-type contact layer 130, the n-side electrostatic breakdown preventing layer 140, and the n-side superlattice layer 150 are n-type semiconductor layers. The p-type cladding layer 170 and the p-type contact layer 180 are p-type semiconductor layers. The n-type semiconductor layer may include an ud-GaN layer (“ud” means undoped, i.e., undoped GaN layer) which is not doped with a donor impurity. The p-type semiconductor layer may include an ud-GaN layer which is not doped with an acceptor impurity.

On the main surface of the substrate 110, the semiconductor layer Ep1 is formed by forming the low-temperature buffer layer 120, the n-type contact layer 130, the n-side electrostatic breakdown preventing layer 140, the n-side superlattice layer 150, the light-emitting layer 160, the p-type cladding layer 170, and the p-type contact layer 180, in this order. The n-electrode N1 is formed on the n-type contact layer 130. The p-electrode P1 is formed on the transparent electrode 190.

The substrate 110 serves as a growth substrate having the main surface on which the above semiconductor layers are formed through MOCVD. The surface of the substrate 110 may be embossed. The substrate 110 is made of sapphire. Other than sapphire, materials such as SiC, ZnO, Si, and GaN may be used.

The low-temperature buffer layer 120 takes over the crystallinity from the substrate 110 and is provided so as to form thereon an upper layer. Thus, the low-temperature buffer layer 120 is formed on the main surface of the substrate 110. The low-temperature buffer layer 120 is made of, for example, AlN or GaN.

The n-type contact layer 130 is provided so as to establish ohmic contact with the n-electrode N1. The n-type contact layer 130 is formed on the low-temperature buffer layer 120. On the n-type contact layer 130, the n-electrode N1 is disposed. The n-type contact layer 130 is formed of n-type GaN and has a Si concentration of 1×10¹⁸/cm³ or greater. Alternatively, the n-type contact layer 130 may be formed of a plurality of layers having different carrier concentrations for enhancing ohmic contact with the n-type electrode N1. The n-type contact layer 130 has a thickness of, for example, 1,000 nm to 10,000 nm. Needless to say, no particular limitation is imposed on the thickness.

The n-side electrostatic breakdown preventing layer 140 serves as an electrostatic breakdown preventing layer for preventing electrostatic breakdown of the semiconductor layers. The n-side electrostatic breakdown preventing layer 140 is formed on the n-type contact layer 130. As shown in FIG. 2, the n-side electrostatic breakdown preventing layer 140 comprises an n-type GaN layer 141, an n-type GaN layer 142, an ud-GaN layer 143, and an n-type GaN layer 144. The ud-GaN layer 143 includes an unintentionally doped GaN layer (ud-GaN: unintentionally doped GaN) other than GaN layer not doped with impurities at all. The ud-GaN layer 143 has a donor concentration of 5×10¹⁷/cm³ or lower. The n-type GaN layer 141 is formed on the n-type contact layer 130. The n-type GaN layer 142 is formed on the n-type GaN layer 141. The ud-GaN layer 143 is formed on the n-type GaN layer 142. The n-type GaN layer 144 is formed on the ud-GaN layer 143. The n-type GaN layer 141 has a thickness of 300 nm to 1,000 nm. The n-type GaN layer 142 has a thickness of 10 nm to 100 nm. The ud-GaN layer 143 has a thickness of 100 nm to 1,000 nm. The n-type GaN layer 144 has a thickness of 10 nm to 100 nm. These thicknesses are merely examples, and other values may be employed.

The n-side superlattice layer 150 is a strain relaxation layer for relaxing the stress applied to the light-emitting layer 160. More specifically, the n-side superlattice layer 150 has a superlattice structure. The n-side superlattice layer 150 is formed on the n-side electrostatic breakdown preventing layer 140. As shown in FIG. 2, the n-side superlattice layer 150 is formed through repeatedly depositing layer units each formed by depositing an ud-InGaN layer 151, an ud-GaN layer 152, and an n-type GaN layer 153. The layers 151 and 152 may be doped with Si. The number of repetitions of the layer units is 10 to 20. However, the number may fall outside the range. The InGaN layer 151 has a thickness of 0.3 nm to 100 nm. The GaN layer 152 has a thickness of 0.3 nm to 10 nm. The n-type GaN layer 153 has a thickness of 0.3 nm to 100 nm. These thicknesses are merely examples, and other values may be employed.

The light-emitting layer 160 emits light through recombination of electrons and holes. The light-emitting layer 160 is formed on the n-side superlattice layer 150. As shown in FIG. 2, the light-emitting layer 160 is formed through repeatedly depositing layer units each formed by depositing a well layer 161, a capping layer 162, and a barrier layer 163. That is, the light-emitting layer 160 has a multiquantum well structure (MQW structure). The capping layer 162 is a protective layer for protecting the well layer 161 from heat. The capping layer 162, for example, plays a role to prevent sublimation of In in the well layer 161. Therefore, the capping layer 162 is disposed on the well layer 161. The barrier layer 163 is disposed on the capping layer 162.

The number of repetitions of depositing the layer units is, for example, 5 to 20. Needless to say, the number may fall outside the range. The well layer 161 is, for example, an ud-InGaN layer. The capping layer 162 is, for example, an ud-GaN layer. The barrier layer 163 is, for example, an ud-AlInGaN layer. The layers 161, 162 and 163 may be doped with Si. The well layer 161 contains In, and the barrier layer 163 contains In.

The In composition ratio of the well layer 161 is greater than the In composition ratio of the barrier layer 163. The In composition ratio of the well layer 161 is 0.05 to 0.30. The In composition ratio of the barrier layer 163 is not greater than 0.01. These numerical value ranges are merely examples, and the In composition ratio is not limited to these ranges.

The thickness of the well layer 161 is 1 nm to 5 nm. The thickness of the capping layer 162 is 0.2 nm to 1.8 nm. The thickness of the barrier layer 163 is 1 nm to 10 nm. These values are merely examples, and other values may be employed. The total thickness of the light-emitting layer 160 is 500 nm to 1,000 nm. Needless to say, other thickness values may be employed.

The p-type cladding layer 170 is formed on the light-emitting layer 160. As shown in FIG. 2, the p-type cladding layer 170 is formed through repeatedly depositing layer units each formed by depositing a p-type InGaN layer 171 and a p-type AlGaN layer 172. The number of repetitions of the layer units is, for example, 5 to 20. Needless to say, the number may fall outside the range. The In composition ratio of the p-type InGaN layer 171 is 0.05 to 0.30. The thickness of the p-type InGaN layer 171 is 0.2 nm to 5 nm. The Al composition ratio of the p-type AlGaN layer 172 is 0.10 to 0.4. The thickness of the p-type AlGaN layer 172 is 1 nm to 5 nm. These values are merely examples, and other values may be employed. The structure of the p-type cladding layer 170 may differ from the one described above.

The p-type contact layer 180 is formed on the p-type cladding layer 170. The thickness of the p-type contact layer 180 is 10 nm to 100 nm. The p-type contact layer 180 is doped with Mg at a concentration of 1×10¹⁹/cm³ to 1×10²²/cm³.

The transparent electrode 190 is formed on the p-type contact layer 180. The material of the transparent electrode 190 is preferably any of ITO, IZO, ICO, ZnO, TiO₂, NbTiO₂, TaTiO₂, and SnO₂.

The p-electrode P1 is formed on the transparent electrode 190. The p-electrode P1 is formed of a Ni layer and an Au layer, sequentially deposited on the transparent electrode 190. Needless to say, other structure may be employed.

The n-electrode N1 is formed on the n-type contact layer 130. The n-electrode N1 is formed of a V layer and an Al layer, sequentially deposited on the n-type contact layer 130. Alternatively, the n-type electrode N1 may be formed by sequentially depositing a Ti layer and an Al layer. Needless to say, other structure may be employed.

The light-emitting device 100 may include a protective film for protecting the semiconductor layer Ep1 et al.

### 2. Pits

### 2-1. Pit Shape

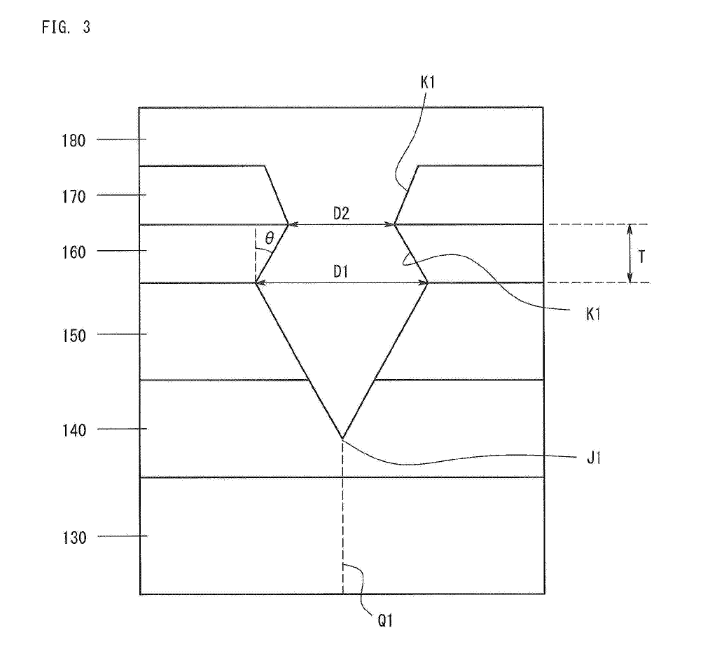

FIG. 3 is a schematic view of a pit K1 provided in the light-emitting device 100. The light-emitting device 100 has a plurality of pits K1 extending from the n-type semiconductor layer to the p-type semiconductor layer. In FIG. 3, a first pit being one of the pits K1 is illustrated. The cross-sectional shape of the pit K1 is almost a regular hexagon. The pit diameters D1 and D2 are a distance between the vertexes located on a diagonal line of the regular hexagon. The pit diameter D1 and D2 are the pit diameter of the first pit.

The pit K1 generates at a threading dislocation Q1 when the semiconductor layer Ep1 of the light-emitting device 100 is grown. In this embodiment, the pit K1 is grown from the n-type GaN layer 142 of the n-side electrostatic breakdown preventing layer 140. The threading dislocation growing upward on the substrate 110 extends laterally i.e., in a direction perpendicular to the growth direction of the threading dislocation inside the film of the n-side electrostatic breakdown preventing layer 140, resulting in the pit K1. The pit K1 grows until reaching the p-type contact layer 180.

The pit K1 starts to grow at the start point J1 of the n-side electrostatic breakdown preventing layer 140, and extends laterally as the growth proceeds. In the n-side electrostatic breakdown preventing layer 140 and the n-side superlattice layer 150, the pit diameter of the pit K1 is increased toward the upper layer. On the other hand, in the light-emitting layer 160, the pit diameter of the pit K1 is decreased toward the upper layer. That is, the pit diameter D1 of the first pit at the interface between the light-emitting layer 160 and the n-side superlattice layer 150, is larger than the pit diameter D2 of the first pit at the interface between the light-emitting layer 160 and the p-type cladding layer 170. The pit K1 extends laterally again in the p-type cladding layer 170.

Thus, the following condition is satisfied.

D1>D2

D1: Pit diameter at the interface between the light-emitting layer and the n-type semiconductor layer

D2: Pit diameter at the interface between the light-emitting layer and the p-type semiconductor layer

### 2-2. Control of Pit Diameter

The pit K1 is considered to generate by reducing the substrate temperature to a specific temperature during the growth of the semiconductor layer Ep1. Therefore, a plurality of pits K1 generate at almost the same depths in the n-side electrostatic breakdown preventing layer 140.

### 2-2-1. Thickness and Growth Temperature

The pit diameter D1 of the pit K1 varies in accordance with the thicknesses of the n-side electrostatic breakdown preventing layer 140 and the n-side superlattice layer 150, and with the growth temperature of the n-side electrostatic breakdown preventing layer 140 and the n-side superlattice layer 150. As the thicknesses of the n-side electrostatic breakdown preventing layer 140 and the n-side superlattice layer 150 are increased, the pit diameter D1 is increased. In contrast, as the thicknesses of the n-side electrostatic breakdown preventing layer 140 and the n-side superlattice layer 150 are decreased, the pit diameter D1 is decreased. Also, as the growth temperatures of the n-side electrostatic breakdown preventing layer 140 and the n-side superlattice layer 150 are increased, the pit diameter D1 is decreased. In contrast, as the growth temperatures of the n-side electrostatic breakdown preventing layer 140 and the n-side superlattice layer 150 are lowered, the pit diameter D1 is increased.

Similarly, as the growth temperature of the light-emitting layer 160 is increased, the pit diameter D2 is decreased.

The relationship between the pit diameter and the growth temperature when growing the n-type semiconductor layer is also satisfied when growing the p-type cladding layer 170 and the p-type contact layer 180.

### 2-2-2. In Doping

The pit diameter is decreased by doping the semiconductor layer Ep1 with In because In has a surfactant effect. Thereby, a flat surface of the semiconductor layer enters the inside of the pit K1. Therefore, the pit diameter tends to be smaller in the semiconductor layer doped with In. In this embodiment, the well layer 161 and the barrier layer 163 of the light-emitting layer 160 are doped with In. The pit diameter tends to be smaller in the light-emitting layer 160. As a result, as mentioned above, the pit diameter D2 at the top of the light-emitting layer 160 is smaller than the pit diameter D1 at the bottom of the light-emitting layer 160 (refer to FIG. 3). The n-side superlattice layer 150 has an InGaN layer 151. Therefore, the pit diameter of the pit K1 in the n-side superlattice layer 150 is a little smaller than the pit diameter of the pit when there is no InGaN layer 151.

### 2-2-3. Growth Temperature of Capping Layer

When the growth temperature of the capping layer 162 is gradually increased from the growth temperature of the well layer 161, the pit diameter D2 is decreased. That is, the substrate temperature at the end of growth of the capping layer 162 is adjusted so as to be higher than that at the start of growth of the capping layer 162. And the substrate temperature in growth of the barrier layer 163 is adjusted at as same as the temperature at the end of growth of the capping layer 162. And the growth temperature at the growth of the next well layer 161 is decreased to the growth temperature of the first well layer 161. Such a growth temperature of increase and decrease described above is repeated in growing of the light-emitting layer 160. Thereby, the pit diameter D2 is decreased. The pit diameter is controlled by migration of atoms due to thermal energy.

### 2-3. Layer Structure Around Pit

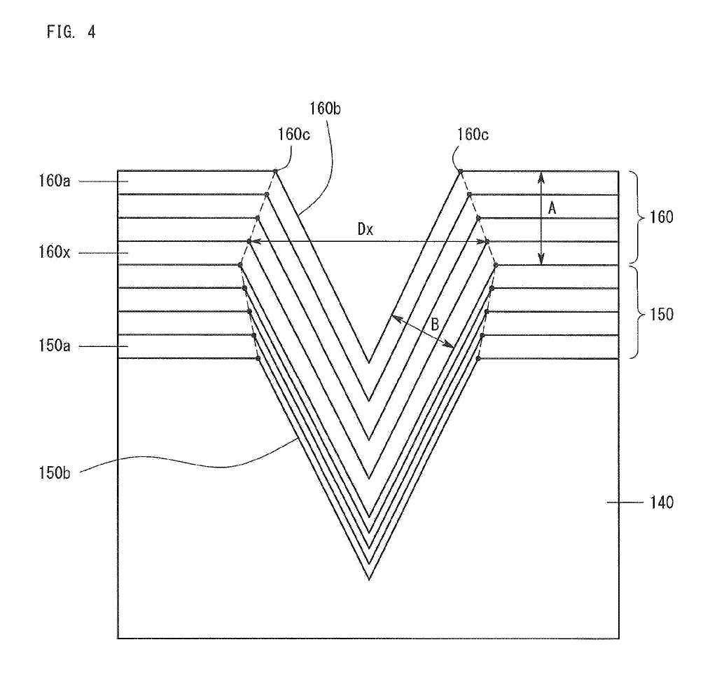

FIG. 4 is a schematic view of a layer structure around the pit K1. As shown in FIG. 4, the n-side superlattice layer 150 has a flat portion 150a and an inclined portion 150b. The light-emitting layer 160 has a flat portion 160a and an inclined portion 160b. The flat portions 150a and 160a are a flat portion disposed outside the pit K1. The inclined portions 150b and 160b are disposed on the inclined surface inside the pit K1. The inclined portions 150b and 160b are connected from the flat portions 150a and 160a respectively.

In FIG. 4, the thickness of the flat portion 150a is equal to the thickness of the flat portion 160a for convenience of drawing. The respective thicknesses are defined as a thickness perpendicular to respective growth surfaces thereof. The thickness of the inclined portion 150b in the n-side superlattice layer 150 is sufficiently thin compared to the thickness of the flat portion 150a. The thickness of the inclined portion 160b in the light-emitting layer 160 is not much different compared to the thickness of the flat portion 160a. The well layer 161 and the barrier layer 163 of the light-emitting layer 160 contain In. The semiconductor layer of the flat portion 160a is considered to enter inside the inclined portion 160b due to surfactant effect of In.

Therefore, when the thicknesses of the flat portions 150a and 160a are the same, the thickness of the inclined portion 160b inside the pit K1 in the semiconductor layer doped with In is considered to be larger than the thickness of the inclined portion 150b inside the pit K1 in the semiconductor layer undoped with In. When the thickness is large inside the pit K1, the pit diameter of the pit K1 is considered to be smaller as the growth proceeds toward the upper layer (refer to FIG. 4). As shown in FIG. 4, the larger the thickness of the inclined portion 160b, the interface 160c between the flat portion 160a and the inclined portion 160b is positioned closer to the center of the pit K1. The pit diameter Dx in the semiconductor layer 160x is, as shown in FIG. 4, a distance connecting the interfaces between the surface of the flat portion and the surface of the inclined portion, and a distance between the vertexes located on a diagonal line of the regular hexagon.

In this embodiment, the thickness A of the flat portion 160a of the light-emitting layer 160 and the thickness B of the inclined portion 160b of the light-emitting layer 160 satisfy the following condition:

0.56≦B/A≦0.9

A: Thickness of the flat portion of the light-emitting layer

B: Thickness of the inclined portion of the light-emitting layer

That is, the thickness B of the inclined portion 160b is slightly smaller than the thickness A of the flat portion 160a.

More preferably, the following condition is satisfied:

0.67≦B/A≦0.8

### 2-4. Pit Diameter Change Rate

The pit diameter change rate F is expressed by the following formula (1).

F=(D1−D2)/T (1)

F: Pit diameter change rate

D1: Pit diameter at the interface between the light-emitting layer and the n-type semiconductor layer

D2: Pit diameter at the interface between the light-emitting layer and the p-type semiconductor layer

T: Thickness of the light-emitting layer

The pit diameter change rate F satisfies the following condition (2).

0.15≦(D1−D2)/T≦1.0 (2)

Preferably, the pit diameter change rate F satisfies the following condition (3).

0.40≦(D1−D2)/T≦0.8 (3)

That is, when the pit diameters D1 and D2 satisfy the above condition (2), especially (3), the reduction of the light emission amount in an operation at a high temperature is suppressed.

### 3. Effect of Pit Diameter

The effect when the semiconductor layer is grown so that the pit diameter is decreased in the light-emitting layer 160 will be described. As described in the experiment section hereinbelow, when the semiconductor layer is grown so that the pit diameter is decreased in the light-emitting layer 160, the emission efficiency of the semiconductor light-emitting device at a high temperature is improved. That is, the emission efficiency at a high temperature is not much different from the emission efficiency at a room temperature.

### 4. Method for Producing Semiconductor Light-Emitting Device

Next will be described the method for producing the light-emitting device 100 according to the embodiment. The semiconductor layers are formed through epitaxial crystal growth by metal-organic chemical vapor deposition (MOCVD). The carrier gas employed in the method is hydrogen (H₂), nitrogen (N₂), or a gas mixture of hydrogen and nitrogen (H₂+N₂). Ammonia gas (NH₃) is employed as a nitrogen source. Trimethylgallium (Ga(CH₃)₃), i.e., TMG, is employed as a Ga source. Trimethylindium (In(CH₃)₃), i.e., TMI, is employed as an In source. Trimethylaluminum (Al(CH₃)₃), i.e., TMA, is employed as an Al source. Silane (SiH₄) is employed as an n-type dopant gas. Bis(cyclopentadienyl)magnesium (Mg(C₅H₅)₂), i.e., Cp₂Mg, is employed as a p-type dopant gas. Any gas other than these may be employed.

4-1. n-type Contact Layer Formation Step

Firstly, the low-temperature buffer layer 120 is formed on the main surface of the substrate 110 at 400° C. with supplying the carrier gas, TMA and NH₃. The n-type contact layer 130, e.g., n-GaN, is formed on the buffer layer 120 with supplying the carrier gas, TMG, NH₃ and silane (SiH₄). The substrate temperature in this step is adjusted to 1,080° C. to 1,140° C.

4-2. n-side Electrostatic Breakdown Preventing Layer Formation Step

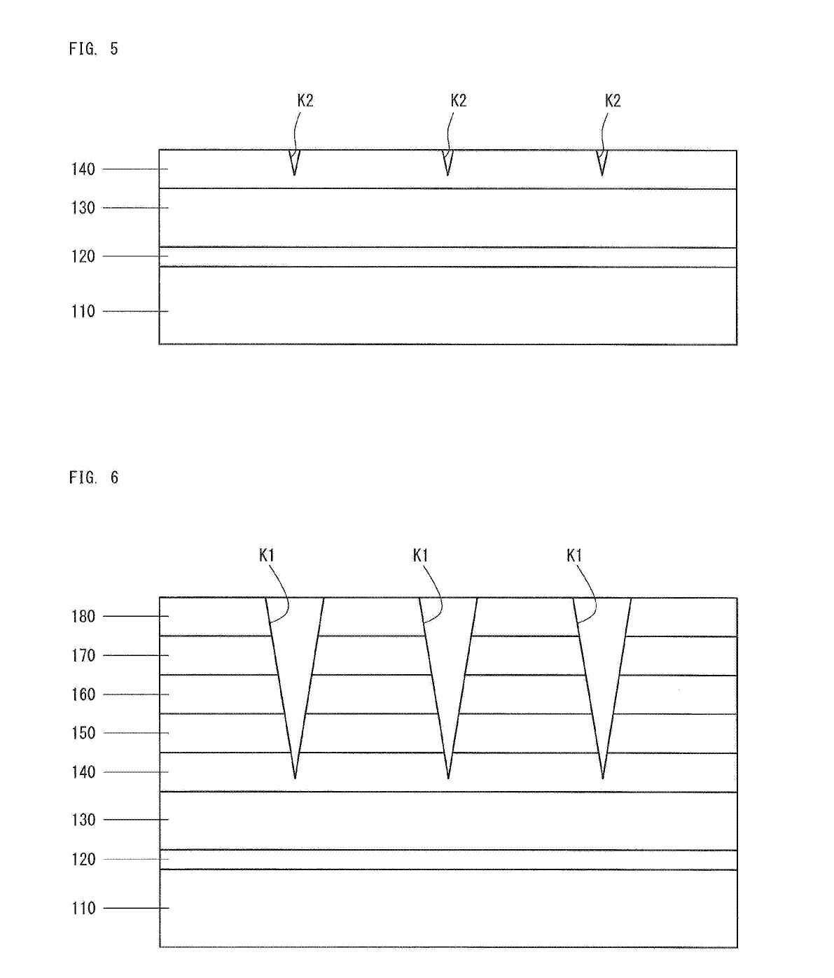

Next, the n-side electrostatic breakdown preventing layer 140 is formed on the n-type contact layer 130. The carrier gas, TMG and NH₃ are commonly continued to be fed in all processes of forming the layer 140. Firstly, silane (SiH₄) is additionally fed, and the n-type GaN layer 141 is formed. Subsequently, silane (SiH₄) is additionally fed, and the n-type GaN layer 142 is formed. Then, only the feed of silane (SiH₄) is stopped, and the ud-GaN layer 143 is formed. Silane (SiH₄) is fed again, and the n-type GaN layer 144 is formed. The temperature of the substrate in the process for growing the n-type GaN layer 141 is any temperature in a range of 1,080° C. to 1,180° C. as same as the growth temperature of the n-type contact layer 130. The temperature of the substrate in the process for growing the n-type GaN layer 142, the ud-GaN layer 143 and the n-type GaN layer 144 is decreased to any temperature, e.g., 880° C., in a range of 750° C. to 950° C. As shown in FIG. 5, the pits K2 are formed in this step because the growth temperature of the semiconductor layer was decreased. The pits K2 grow as the growth of the semiconductor layer proceeds, resulting in pits K1. In this way, while the pits K2 are formed, the n-side electrostatic breakdown preventing layer 140 is formed.

4-3. n-side Superlattice Layer Formation Step

Then, n-side superlattice layer 150 is formed. The growth temperature is any constant temperature, e.g., 855° C., in a range of 750° C. to 950° C. and the carrier gas, TMG and NH₃ are commonly continued to be fed in all processes of forming the layer 150. Firstly, the ud-InGaN layer 151 is formed on the n-type GaN layer 144 of the n-side electrostatic breakdown preventing layer 140 with additionally supplying TMI. Subsequently, after stopping feeding of TMI, the ud-GaN layer 152 is formed on the ud-InGaN layer 151. Then, the n-type GaN layer 153 is formed on the ud-GaN layer 152 with additionally supplying silane (SiH₄). In this way, layer units each formed by depositing the ud-InGaN layer 151, the ud-GaN layer 152, and the n-type GaN layer 153, are repeatedly deposited.

### 4-4. Light-Emitting Layer Formation Step

Subsequently, the light-emitting layer 160 is formed on the n-side superlattice layer 150. The carrier gas, TMG and NH₃ are commonly continued to be fed in all processes of forming the layer 160. Layer units each formed by depositing the well layer 161, e.g., InGaN, the capping layer 162, e.g., a double layer of GaN and AlGaN (hereinafter “GaN/AlGaN”), and the barrier layer 163, e.g., AlGaN doped with In in a range of In concentration of 5×10¹⁸/cm³ to 5×10²⁰/cm³, in this order, are repeatedly deposited. The In concentration of the barrier layer 163 is more preferably 1×10¹⁹/cm³ to 1×10²⁰/cm³. InGaN of the well layer 161 is grown with additionally supplying TMI, GaN/AlGaN of the capping layer 162 is grown with additionally supplying TMA and AlGaN of the barrier layer 163 is grown with additionally supplying TMA and TMI. The light-emitting layer formation step comprises the well layer formation step of forming the well layer 161, the capping layer formation step of forming the capping layer 162 on the well layer 161, and the barrier layer formation step of forming the barrier layer 163 on the capping layer 162. These steps are repeatedly performed. Therefore, the well layer 161 is formed again on the barrier layer 163. The substrate temperature when growing the well layer 161 is adjusted to any temperature, e.g., 800° C., in a range of 730° C. to 850° C. The growth temperature of the capping layer 162 is increased from the temperature of the well layer 161. And also the preferable growth temperature range of the barrier layer 163 is 770° C. to 1000° C. higher than the growth temperature of the well layer 161. The preferable increase amount of the growth temperature in growing the capping layer 162 is 40° C. to 150° C.

When growing the light-emitting layer 160, the semiconductor layers are grown so as to satisfy the following three conditions: (1) The barrier layer 163 is doped with a very small amount of In when growing the barrier layer 163, (2) The temperature is increased when growing the light-emitting layer 160, (3) The substrate temperature is not constant but gradually increased when growing the capping layer 162. Thereby, the pit diameter D2 of the pit K1 can be decreased. Needless to say, these three conditions are not necessarily satisfied at the same time. If these conditions are partially satisfied, the pit diameter D2 tends to be smaller.

4-5. p-type Cladding Layer Formation Step

Then, the p-type cladding layer 170 is formed on the light-emitting layer 160. The carrier gas, TMG, NH₃ and Cp₂Mg are commonly continued to be fed in all processes of forming the layer 170. In this step, the p-type InGaN layer 171 with additionally supplying TMI and the p-type AlGaN layer 172 with additionally supplying TMA are repeatedly deposited.

4-6. p-type Contact Layer Formation Step

Then, the p-type contact layer 180, e.g., p-GaN, is formed on the p-type cladding layer 170 with supplying the carrier gas, TMG, NH₃ and Cp₂Mg. The substrate temperature is adjusted at any temperature, e.g., 1040° C., in a range of 900° C. to 1,050° C. Since the growth temperature of the p-type contact layer 180 is high, the pits K1 are filled with the p-type contact layer 180. Thereby, as shown in FIG. 6, semiconductor layers are deposited on the substrate 110. At this time, the pits K1 are formed so as to extend from the n-side electrostatic breakdown preventing layer 140 to the p-type contact layer 180. Therefore, there are no pits K1 on the surface of the p-type contact layer 180.

### 4-7. Transparent Electrode Formation Step

Next, the transparent electrode 190 is formed on the p-type contact layer 180.

### 4-8. Electrode Formation Step

Then, the p-electrode P1 is formed on the transparent electrode 190. The semiconductor layer deposited structure is partially removed through laser radiation or etching from the p-type contact layer 180, to thereby expose the n-type contact layer 130. The n-electrode N1 is formed on the exposed area of the n-type contact layer 130. Formation of the p-electrode P1 and formation of the electrode N1 may be carried out in any order.

### 4-9. Other Steps

In addition to the aforementioned steps, thermal treatment, insulating film formation and other steps may be performed. Through carrying out the steps, the light-emitting device 100 shown in FIG. 1 is produced.

### 5. Experiments

### 5-1. Relationship Between Growth Conditions of Semiconductor Layer and Pit Diameter

Firstly, experiments were performed to investigate the relationship between the growth conditions of the semiconductor layer and the pit diameter. The three conditions to decrease the pit diameter when growing the light-emitting layer 160 are as follows. (1) The barrier layer 163 is doped with a very small amount of In when growing the barrier layer 163, (2) The temperature is increased when growing the light-emitting layer 160, (3) The substrate temperature is not constant but gradually increased when growing the capping layer 162.

As shown in Table 1, the total thickness of the light-emitting layer 160 was approx. 68 nm. When the semiconductor layer was grown up to the n-side electrostatic breakdown preventing layer 140, the pit diameter on a surface of the layer 140 was 169.6 nm. When the semiconductor layer was grown up to the n-side superlattice layer 150, the pit diameter on a surface of the layer 150 was 234.9 nm. The In composition ratio of the well layer 161 was 0.24.

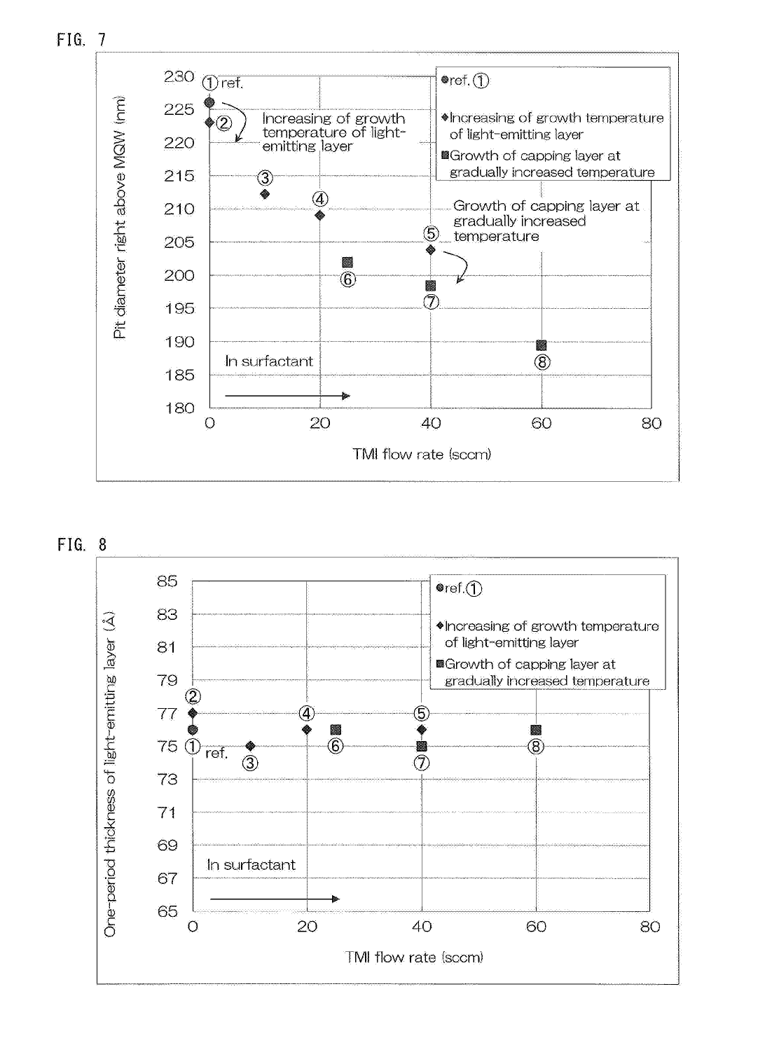

FIG. 7 is a graph showing the above three conditions. The horizontal axis of FIG. 7 is TMI flow rate (sccm). The vertical axis of FIG. 7 indicates the pit diameter D2. As shown in FIG. 7, the larger the amount of In that the barrier layer 163 is doped with, the smaller the pit diameter D2. When each layer of the light-emitting layer 160 is grown at a higher temperature than the growth temperature of the respective corresponding layer of conventional device, the pit diameter D2 is smaller. When the capping layer 162 is grown while increasing the substrate temperature, the pit diameter D2 tends to be smaller. The growth temperature of each layer of the light-emitting layer 160 was higher only by 5° C. than the growth temperature of the respective corresponding layer of conventional device. In FIG. 7, when the TMI flow rate was zero, the amount of In that the barrier layer 163 is doped with was zero. However, even in that case, TMI was fed when growing the well layer 161.

FIG. 8 is a graph obtained by plotting one-period thickness vs. the TMI flow rate of the light-emitting layer 160. The horizontal axis of FIG. 8 indicates the TMI flow rate (sccm). The vertical axis of FIG. 8 indicates the one-period thickness of the light-emitting layer 160. As shown in FIG. 8, even if the production conditions are changed, the one-period thickness of the light-emitting layer 160 is hardly changed. The graph shows that even if the above three conditions are changed, the growth rate in the thickness direction (vertical direction) is not affected, and the growth rate in the pit diameter direction (horizontal direction, i.e., a direction perpendicular to the thickness direction) is changed.

### 5-2. Total Radiant Flux and Drive Voltage of Light-Emitting Device at Room Temperature

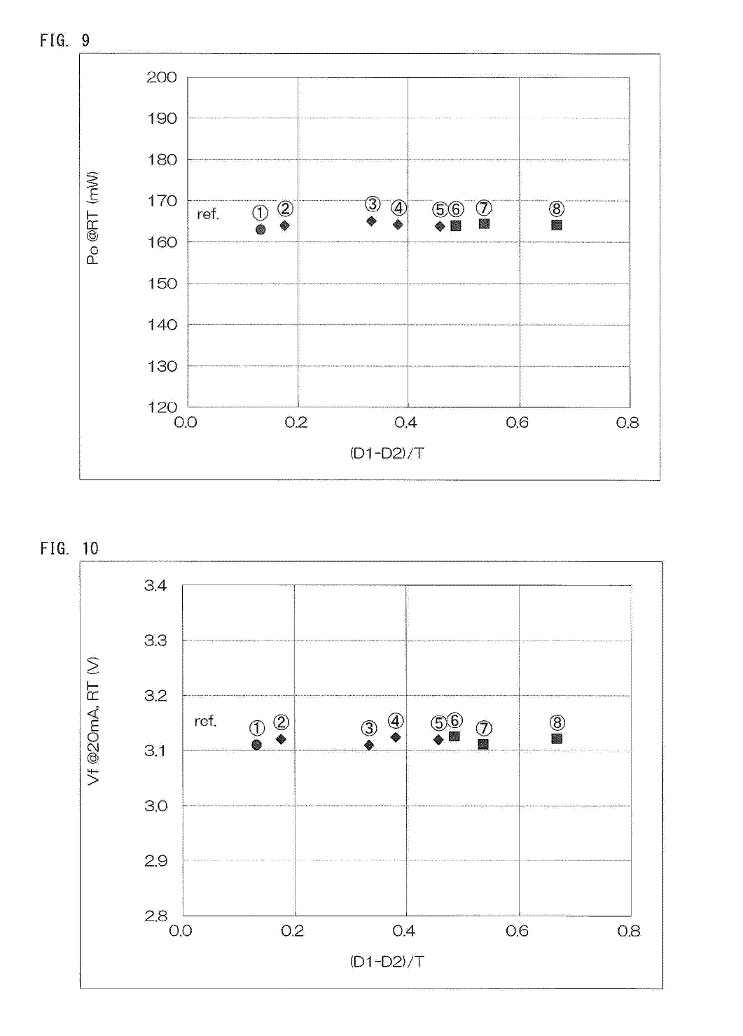

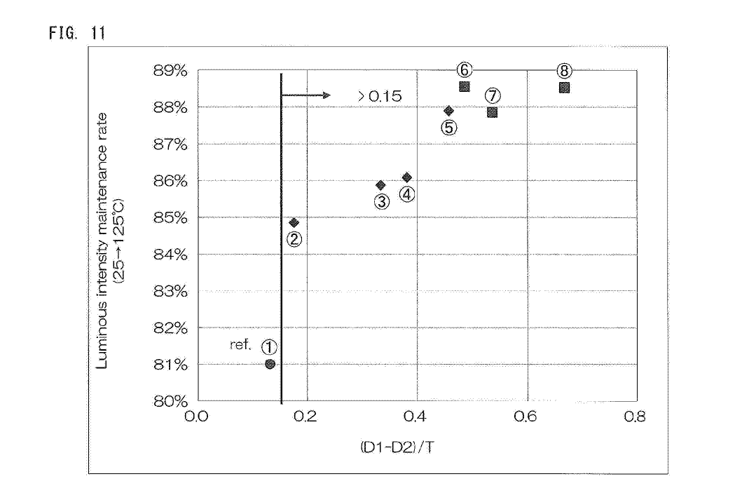

FIG. 9 is a graph showing the total radiant flux of the light-emitting device at a room temperature. The symbol “@” means “at” in FIG. 9, FIG. 10 and Table 1. The horizontal axis of FIG. 9 indicates (D1−D2)/T. The vertical axis of FIG. 9 indicates the total radiant flux (mW). As shown in FIG. 9, even if (D1−D2)/T is changed, the total radiant flux of the light-emitting device at a room temperature hardly changed. That is, the total radiant flux of the light-emitting device at a room temperature hardly changed, even if any one of three conditions is changed: (1) the TMI flow rate, (2) the growth temperature of the light-emitting layer, and (3) the growth of the capping layer at gradually increased temperature.

FIG. 10 is a graph showing the drive voltage of the light-emitting device at a room temperature. The horizontal axis of FIG. 10 indicates (D1−D2)/T. The vertical axis of FIG. 10 indicates the drive voltage (V). As shown in FIG. 10, even if (D1−D2)/T is changed, the drive voltage of the light-emitting device at a room temperature hardly changed. That is, the drive voltage of the light-emitting device at a room temperature hardly changed, even if any one of three conditions is changed: (1) the TMI flow rate, (2) the growth temperature of the light-emitting layer, and (3) the growth of the capping layer at gradually increased temperature.

In this way, the performance of the light-emitting device at a room temperature hardly changed even if the above three conditions are changed.

### 5-3. Relationship Between Pit Diameter Change Rate and Luminous Intensity Maintenance Rate

FIG. 11 is a graph showing the pit diameter change rate and the luminous intensity maintenance rate. The horizontal axis of FIG. 11 indicates the pit diameter change rate F. The vertical axis of FIG. 11 indicates the luminous intensity maintenance rate. The pit diameter change rate F is expressed by the above-mentioned formula (1).

When the pit diameter change rate F is a positive value, as shown in FIG. 4, the light-emitting layer 160 is grown so that the pit diameter is decreased. The larger the pit diameter change rate F, the more rapidly the pit diameter is decreased as the growth proceeds. On the other hand, when the pit diameter change rate F is a negative value, the light-emitting layer 160 is grown so that the pit diameter is increased.

The luminous intensity maintenance rate is the total radiant flux of the light-emitting device at a high temperature (125° C.) to the total radiant flux of the light-emitting device at a room temperature (25° C.). That is, when the luminous intensity maintenance rate is 100%, the luminance of the light-emitting device at a high temperature (125° C.) is equal to the luminance of the light-emitting device at a room temperature (25° C.). The lower the luminous intensity maintenance rate, the smaller the total radiant flux at a high temperature than the total radiant flux at a low temperature.

As shown in FIG. 11, when the pit diameter change rate F is 0.15 to 1.0, the luminous intensity maintenance rate is 84% or more. Therefore, the pit diameter change rate F is, preferably, within a range of 0.15 to 1.0. When the pit diameter change rate F is 0.4 to 0.8, the luminous intensity maintenance rate is 87% or more. Therefore, the pit diameter change rate F is, more preferably, within a range of 0.4 to 0.8.

As shown in Table 1, when the ratio (B/A) of the thickness B of the inclined portion 160b of the light-emitting layer 160 to the thickness A of the flat portion 160a of the light-emitting layer 160 is 0.56 to 0.9, the luminous intensity maintenance rate is 84% or more. Therefore, the thickness ratio B/A is, preferably, 0.56 to 0.9. Moreover, when the thickness ratio B/A is 0.67 to 0.8, the luminous intensity maintenance rate is 87% or more. Therefore, the thickness ratio B/A is, more preferably, 0.67 to 0.8.

TABLE l

| | Conditions | | | | | | | | | | |
|---|---|---|---|---|---|---|---|---|---|---|---|
| | | Increasing of | | Measure- | | | | | Luminous | | |
| | | growth | Growth of | ment result | Calculated value | | | | intensity | | |
| | | temperature | capping layer | Pit | Inclined | Inclined | | | maintenance | Po | Vf |
| Sample | TMI | of light- | at increased | diameter | surface | surface/Flat | | | rate | @RT | @RT |
| No. | (sccm) | emitting layer | temperature | (nm) | (nm) | surface | D1-D2 | (D1-D2)/T | (25→125° C.) | (mW) | (V) |
| \textcircled{1} | 0 | | | 226.0 | 38 | 0.557 | 8.9 | 0.131 | 81.0% | 163.0 | 3.110 |
| \textcircled{2} | 0 | ◯ | | 223.0 | 39 | 0.576 | 11.9 | 0.176 | 84.9% | 164.0 | 3.120 |
| \textcircled{3} | 10 | ◯ | | 212.3 | 44 | 0.644 | 22.7 | 0.334 | 85.9% | 165.1 | 3.109 |
| \textcircled{4} | 20 | ◯ | | 209.0 | 45 | 0.665 | 25.9 | 0.381 | 86.1% | 164.2 | 3.124 |
| \textcircled{5} | 40 | ◯ | | 203.8 | 47 | 0.698 | 31.1 | 0.457 | 87.9% | 163.8 | 3.119 |
| \textcircled{6} | 25 | ◯ | ◯ | 201.9 | 48 | 0.710 | 33.0 | 0.485 | 88.6% | 164.0 | 3.126 |
| \textcircled{7} | 40 | ◯ | ◯ | 198.4 | 50 | 0.732 | 36.5 | 0.537 | 87.9% | 164.6 | 3.112 |
| \textcircled{8} | 60 | ◯ | ◯ | 189.5 | 54 | 0.790 | 45.5 | 0.669 | 88.5% | 164.1 | 3.122 |
| | Up to | — | — | 234.9 | | | | | | | |
| | n-SL layer | | | | | | | | | | |
| | up to | — | — | 169.6 | | | | | | | |
| | ESD layer | | | | | | | | | | |

*ESD layer: Electrostatic breakdown preventing layer
Thickness of light-emitting layer: 68 nm

### 6. Variations

### 6-1. Filling in Pit

In the above embodiment, the pits K1 extend from the n-side electrostatic breakdown preventing layer 140 to the p-type contact layer 180. That is, the pits K1 are filled with the p-type contact layer 180. However, the pits K1 may be filled with the p-type cladding layer 170. The pits K1 are still formed so as to extend from the n-type semiconductor layer to the p-type semiconductor layer. Thus, the pits K1 may be filled in the middle of the p-type semiconductor layer.

### 6-2. Light-Emitting Layer

In the above embodiment, the light-emitting layer 160 is formed by repeatedly depositing layer units each being formed of the well layer 161, the capping layer 162, and the barrier layer 163. However, the capping layer 162 may be omitted. In that case, the growth temperature of the barrier layer 163 is increased from the growth temperature of the well layer 161 and the layer units each being formed of the well layer 161 and the barrier layer 163 may be repeatedly deposited. When the capping layer 162 is formed, the capping layer 162 may doped with In as well as the barrier layer 163.

### 6-3. Flip-Chip Type

The light-emitting device 100 of the embodiment is of a face-up type. However, the techniques of the embodiment are applicable to a flip-chip type light-emitting device and a laser lift-off type light-emitting device.

6-4. n-side Electrostatic Breakdown Preventing Layer

In the above embodiment, the n-side electrostatic breakdown preventing layer 140 has a four-layer structure. However, other structure may be employed. The starting point J1 of the pit K1 is preferably inside the thickness of the n-side electrostatic breakdown preventing layer 140.

### 7. Summary of the Embodiment

As described above in detail, in the light-emitting device 100 of the embodiment, the well layer 161 and the barrier layer 163 of the light-emitting layer 160 are doped with In. Therefore, the semiconductor layer of the flat portion 160a enters inside the pit K1 due to In surfactant effect of the light-emitting layer 160. Thereby, the thickness of the inclined portion 160b of the light-emitting layer 160 is increased to a certain degree. At the same time, when the light-emitting layer 160 is grown, the pit diameter of the pit K1 is slightly decreased. Thus, a semiconductor light-emitting device exhibiting high emission efficiency is achieved even at a high temperature.

The above-described embodiment is merely an example. Accordingly, needless to say, the embodiment may be improved or modified in various ways without departing from the scope of the present techniques. The depositing structure of the layered body is not necessarily limited to the above-illustrated structure. The depositing structure, the number of repetitions of layers, etc. may be freely selected. The vapor deposition method is not limited to the metal organic chemical vapor deposition (MOCVD). Any other vapor deposition method may be used so long as it uses a carrier gas to grow crystals. The semiconductor layers may be through another epitaxial growth method such as liquid-phase epitaxy or molecular beam epitaxy.

What is claimed is:

1. A Group III nitride semiconductor light-emitting device comprising:
an n-type semiconductor layer,
a light-emitting layer on the n-type semiconductor layer, and
a p-type semiconductor layer on the light-emitting layer, wherein
there is a plurality of pits extending from the n-type semiconductor layer to the p-type semiconductor layer;
a pit diameter D1 of a first pit of the pits at an interface between the light-emitting layer and the n-type semiconductor layer is larger than a pit diameter D2 of the first pit at an interface between the light-emitting layer and the p-type semiconductor layer; and
the pit diameter D1 and the pit diameter D2 satisfy the following condition:
0.15≦(D1−D2)/T≦1.0
T: Thickness of the light-emitting layer

2. The Group III nitride semiconductor light-emitting device according to claim 1, wherein the light-emitting layer has a flat portion disposed outside the first pit and an inclined portion disposed inside the first pit and connected from the flat portion; and
thicknesses of the flat portion and the inclined portion satisfy the following condition:
0.56≦B/A≦0.9
A: Thickness of the flat portion of the light-emitting layer
B: Thickness of the inclined portion of the light-emitting layer

3. A Group III nitride semiconductor light-emitting device according to claim 1, wherein
the light-emitting layer comprises a well layer, a barrier layer doped with In.

4. A Group III nitride semiconductor light-emitting device according to claim 1, wherein
the light-emitting layer comprises an InGaN well layer, a capping layer and an AlGaN barrier layer doped with In.

5. A Group III nitride semiconductor light-emitting device according to claim 4, wherein
the capping layer comprises a GaN layer and an AlGaN layer.

6. A method for producing a Group III nitride semiconductor light-emitting device comprising:
forming an n-type semiconductor layer,
forming a light-emitting layer on the n-type semiconductor layer, and
forming a p-type semiconductor layer on the light-emitting layer, wherein
a plurality of pits are formed so as to extend from the n-type semiconductor layer to the p-type semiconductor layer;
a pit diameter D1 of a first pit of the pits at an interface between the light-emitting layer and the n-type semiconductor layer is larger than a pit diameter D2 of the first pit at an interface between the light-emitting layer and the p-type semiconductor layer; and
the pit diameter D1 and the pit diameter D2 satisfy the following condition:
0.15≦(D1−D2)/T≦1.0
T: Thickness of the light-emitting layer

7. The method for producing a Group III nitride semiconductor light-emitting device according to claim 6, wherein the light-emitting layer has a flat portion disposed outside the first pit and an inclined portion disposed inside the first pit and connected from the flat portion; and
the pits are formed so that thicknesses of the flat portion and the inclined portion satisfy the following condition:
0.56≦B/A≦0.9
A: Thickness of the flat portion of the light-emitting layer
B: Thickness of the inclined portion of the light-emitting layer

8. The method for producing a Group III nitride semiconductor light-emitting device according to claim 6, wherein as the light-emitting layer, an InGaN well layer, a capping layer on the well layer, and a barrier layer containing In on the capping layer are formed; and
the temperature is gradually increased when forming the capping layer.

9. The method for producing a Group III nitride semiconductor light-emitting device according to claim 7, wherein as the light-emitting layer, an InGaN well layer, a capping layer on the well layer, and a barrier layer containing In on the capping layer are formed; and
the temperature is gradually increased when forming the capping layer.

10. The method for producing a Group III nitride semiconductor light-emitting device according to claim 8,
wherein the capping layer comprises a GaN layer and an AlGaN layer and the barrier layer comprises AlGaN.
